(19) United States
(12) Patent Application Publication
(10) Pub. No.: US 2009/0071505 A1
(43) Pub. Date: Mar. 19, 2009

(54) CLEANING METHOD AND SUBSTRATE PROCESSING APPARATUS

(75) Inventors: Hironobu Miya, Toyama-shi (JP); Yuji Takebayashi, Toyama-shi (JP); Masanori Sakai, Takaoka-shi (JP); Shinya Sasaki, Toyama-shi (JP); Hirohisa Yamazaki, Toyoma-shi (JP); Atsuhiko Suda, Toyama-shi (JP)

Correspondence Address: MATTINGLY, STANGER, MALUR & BRUNDIDGE, P.C., 1800 DIAGONAL ROAD, SUITE 370, ALEXANDRIA, VA, 22314, US

(73) Assignee: Hitachi-Kokusai Electric Inc.

(21) Appl. No.: 12/188,440

(22) Filed: Aug. 8, 2008

(30) Foreign Application Priority Data
Sep. 19, 2007 (JP) 2007-242671

(51) Int. Cl. B08B 7/00; C23C 16/00

(52) U.S. Cl. 134/1.1; 134/4; 118/715

(57) ABSTRACT

Provided is a cleaning method which can efficiently remove a film, such as a high dielectric constant oxide film, which is difficult to be etched by a fluorine-containing gas alone. As a cleaning method of a substrate processing apparatus which forms a desired film on a wafer by supplying a source gas, there is provided a cleaning method for removing a film attached to the inside of a processing chamber. The cleaning method includes: a step of supplying a halogen-containing gas into the processing chamber; and a step of supplying a fluorine-containing gas into the processing chamber, after starting the supply of the halogen-containing gas, wherein, in the step of supplying the fluorine-containing gas, the fluorine-containing gas is supplied while supplying the halogen-containing gas into the processing chamber.

### CROSS-REFERENCE TO RELATED PATENT APPLICATION

This U.S. non-provisional patent application claims priority under 35 U.S.C. §119 of Japanese Patent Application No. 2007-242671, filed on Sep. 19, 2007, in the Japanese Patent Office, the entire contents of which are hereby incorporated by reference.

### BACKGROUND OF THE INVENTION

1. Field of the Invention

The present invention relates to a cleaning method, and more particularly, to a cleaning method of a substrate processing apparatus which forms a desired film by supplying a substrate processing gas to a substrate.

2. Description of the Prior Art

Recently, as semiconductor devices are getting denser, gate dielectric films become thinner and gate currents increase. As a solution to solve this problem, gate dielectric films are made of high dielectric constant oxide layers, for example, a hafnium oxide (HfO₂) film or a zirconium oxide (ZrO₂) film. Furthermore, to increase the capacity of DRAM capacitor, high dielectric constant oxide films have been applied. These high dielectric constant oxide films should be grown at a low temperature, and also requires a film formation method having excellent surface roughness property, recess filling property, step coverage property, and few foreign particles.

To remove the foreign particles, conventionally, a reaction tube is taken off and a wet etching (etching cleaning) is performed on the reaction tube. Recently, a removing method of a semiconductor film deposited on the inner wall of the reaction tube by gas cleaning, without taking off the reaction tube, has been generally used. As the gas cleaning method, there are a method of exciting an etching gas by plasma, and a method of exciting an etching gas by heat. A plasma etching often uses a single wafer type apparatus in the viewpoint of the uniformity of plasma density and the control of bias voltage. Meanwhile, a thermal etching often uses a vertical type apparatus. To suppress the peeling of a deposited film from the wall of the reaction tube or parts such as a boat, an etching process is performed whenever a deposited film of predetermined thickness is formed.

Many reports on the etching of a high dielectric constant oxide film have been published as follows. For example, the non-patent document 1 discloses the etching of an HfO₂ film by BCl₃/N₂ plasma, and the non-patent document 2 discloses the etching of a ZrO₂ film by Cl₂/Ar plasma. The non-patent document 3 and the non-patent document 4 disclose the etching of an HfO₂ film and a ZrO₂ film by BCl₃/Cl₂ plasma. Furthermore, the patent document 1 discloses the etching using BCl₃. As such, in the conventional etching of the high dielectric constant oxide film, researches have been conducted mainly on plasma treatment using chlorine-based etching gas.

[Non-patent Document 1] K. J. Nordheden and J. F. Sia, J. Appl. Phys., Vol. 94, (2003) 2199

[Non-patent Document 2] Sha. L., Cho. B. O., Chang. P. J., J. Vac. Sci. Technol. A20(5), (2002) 1525

[Non-patent Document 3] Sha. L., Chang. P. J., J. Vac. Sci. Technol. A21(6), (2003) 1915

[Non-patent Document 4] Sha. L., Chang. P. J., J. Vac. Sci. Technol. A22(1), (2004) 88

[Patent Document 1] Japanese Patent Publication No. 2004-146787

By the way, conventionally, the etching of the high dielectric constant oxide film by using the fluorine-containing gas, such as ClF₃, as the cleaning gas, has been executed widely. However, in the case where the etching is executed by using the fluorine-containing gas alone, fluoride of a metal element composing the high dielectric constant oxide film is attached to the surface of an etching target film of the high dielectric constant oxide film to be etched, so that it is difficult to remove the high dielectric constant oxide film. For example, in the case where ClF₃ is used as the fluorine-containing gas, and an HfO₂ film as the high dielectric constant oxide film is subjected to be etched, if the etching is executed by ClF₃ alone, fluoride of Hf is attached to the surface of the etching target film, so that it is difficult to remove the HfO₂ film.

### SUMMARY OF THE INVENTION

Therefore, a major object of the present invention is to provide a cleaning method which is capable of effectively removing a film such as a high dielectric constant oxide film that is difficult to be etched by a fluorine-containing gas alone.

According to an aspect of the present invention, there is provided a cleaning method for removing a film attached to the inside of a processing chamber of a substrate processing apparatus which forms a desired film on a substrate by supplying a source gas, the cleaning method including: a step of supplying a halogen-containing gas into the processing chamber; and a step of supplying a fluorine-containing gas into the processing chamber, after starting the supply of the halogen-containing gas, wherein, in the step of supplying the fluorine-containing gas, the fluorine-containing gas is supplied while supplying the halogen-containing gas into the processing chamber.

According to another aspect of the present invention, there is provided a cleaning method for removing a first high dielectric constant oxide film attached to the inside of a processing chamber of a substrate processing apparatus which forms a second high dielectric constant oxide film on a substrate by supplying a source gas, the cleaning method including: a step of supplying a mixed gas of a halogen-containing gas and a fluorine-containing gas into the processing chamber, wherein, by the supply of the halogen-containing gas and the fluorine-containing gas, termination group existing on the surface of the first high dielectric constant oxide film is substituted with a halogen element, an oxygen element bonded with a metal element contained in the first high dielectric constant oxide film is substituted with a halogen element or a fluorine element, and a product composed of the metal element, the halogen element and the fluorine element is formed.

According to another aspect of the present invention, there is provided a substrate processing apparatus, including: a processing chamber for processing a substrate; a first supply pipeline for supplying a substrate processing gas into the processing chamber; a second supply pipeline for supplying a halogen-containing gas into the processing chamber; a third supply pipeline for supplying a fluorine-containing gas into the processing chamber; and a controller for controlling the second supply pipeline and the third supply pipeline, first supplying the halogen-containing gas through the second supply pipeline into the processing chamber, and then supplying the fluorine-containing gas through the third supply pipeline into the processing chamber.

### BRIEF DESCRIPTION OF THE DRAWINGS

FIG. 1A is a drawing schematically showing the relation between vapor pressure and temperature in fluoride and chloride of Hf compounds.

FIG. 1B is a drawing schematically showing the relation between vapor pressure and temperature in fluoride, chloride and bromide of Zr compounds.

FIG. 2A and FIG. 2B are drawings schematically showing desorption of a molecule occurring in a Si surface.

FIG. 3 is a drawing schematically showing adsorption of Cl on an HfO₂ surface.

FIG. 4 is a drawing schematically showing desorption of HfClₓF_{y} from an HfO₂ surface.

FIG. 5 is a drawing showing an example (gas supply method 1) of a supplying method of a fluorine-based etching gas and a chlorine-based etching gas.

FIG. 6 is a drawing showing an example (gas supply method 2) of a supplying method of a fluorine-based etching gas and a chlorine-based etching gas.

FIG. 7 is, a perspective view showing schematic configuration of a substrate processing apparatus used as a preferred embodiment of the present invention.

FIG. 8 is a side cross-sectional view showing schematic configuration of the substrate processing apparatus used in the preferred embodiment of the present invention.

FIG. 9 is a drawing showing schematic configuration of a processing furnace and members accompanying therewith used in the preferred embodiment of the present invention, and in particular, a longitudinal cross-sectional view of the processing furnace part.

FIG. 10 is a cross-sectional view taken along the A-A line of FIG. 9.

### DETAILED DESCRIPTION OF THE PREFERRED EMBODIMENTS

Hereinafter, explanation will be given on cleaning methods relevant to preferred embodiments of the present invention with reference to the attached drawings. The cleaning methods relevant to this invention are executed by using etching phenomenon. In the present invention, the term “etching” used herein has the substantially same meaning as “cleaning”.

[Etching Principle]

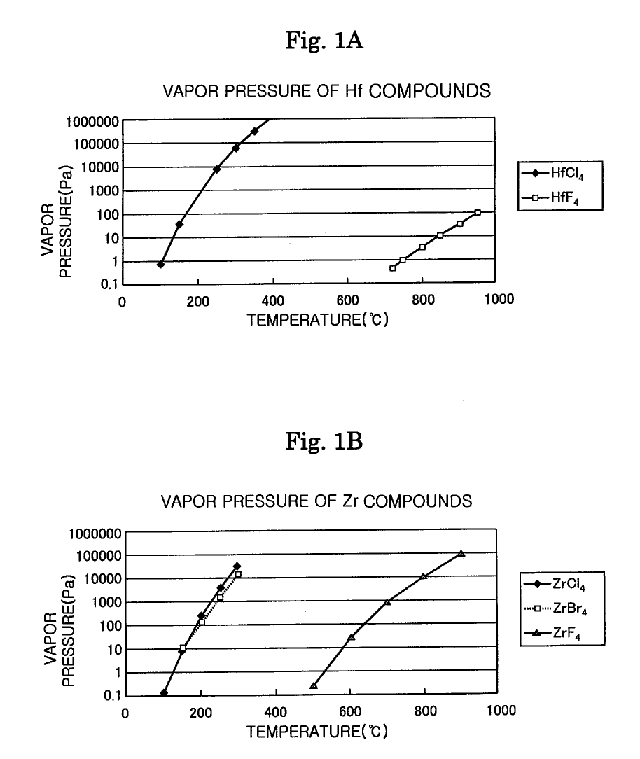

FIG. 1A and FIG. 1B show vapor pressures of fluorides and halides of Hf and Zr (chlorides, bromides (Zr only)). The vapor pressure of the halide is higher than that of the fluoride, so it is considered that halogen-based gas is suitable for an etching process. In addition, as shown in the following Table 1, the bond energy of Hf—O bond and the bond energy of Zr—O bond are as high as 8.30 eV and 8.03 eV respectively, and oxides of Hf and Zr are materials that difficult to be etched. The etching requires a process of breaking the Hf—O bond and the Zr—O bond, a process of forming chlorides and bromides of Hf and Zr, and a process of releasing reaction product.

TABLE 1

| | Bond energy | | Bond energy |
|---|---|---|---|
| Bond | (eV) | Bond | (eV) |
| B—O | 8.38 | Si—O | 8.29 |
| B—F | 7.85 | Si—F | 5.73 |
| B—Cl | 5.30 | Si—Cl | 4.21 |
| B—Br | 4.11 | Si—Br | 3.81 |
| | | Si—Si | 3.39 |
| C—O | 11.15 | Zr—O | 8.03 |
| C—F | 5.72 | Zr—F | 6.38 |
| C—Cl | 4.11 | Zr—Cl | 5.11 |
| C—Br | 2.90 | Zr—Br | — |
| Al—O | 5.30 | Hf—O | 8.30 |
| Al—F | 6.88 | Hf—F | 6.73 |
| Al—Cl | 5.30 | Hf—Cl | 5.16 |
| Al—Br | 4.45 | Hf—Br | — |

Herein, to examine the etching mechanism briefly, it is assumed that the HfO₂ film is etched by ClF₃ gas and thermal etching by Cl₂.

In the case where the HfO₂ film is etched by ClF₃, the reaction proceeds as follows:

ClF₃→ClF+F₂ (1)

HfO₂+2F₂→HfF₄+O₂ (2)

If ClF₃ etching is performed at 300 to 500° C., it is expected from the vapor pressure curve of HfF₄, shown in FIG. 1A, that HfF₄ is formed and simultaneously deposited on the surface of the film.

As shown in FIG. 1A, which also shows the vapor pressure curve of HfCl₄, it can be known that it is possible to obtain enough vapor pressure not to generate residue after the etching in a temperature range of 300 to 500° C. As explained in the above “Description of the Prior Art” section, the studies on the etching of the high dielectric constant oxide film have been focused on the chlorine-based etching gas because the vapor pressure of the chlorine-based gas is high.

If the high dielectric constant oxide film is thermally etched by ClF₃ in practice, it can be known that the etching is possible in a certain condition range. However, in the case where the etching gas is Cl₂ or HCl, the etching does not proceed. This is because the bond energy of Hf—O is 8.30 eV and the bond energy of Hf—Cl is 5.16 eV, as shown in the above Table 1, so that the Hf—O bond cannot be broken. The bond energies of the above Table 1 are abstracted from Lide. D. R. ed. CRC handbook of Chemistry and Physics, 79^{th} ed., Boca Raton, Fla., CRC Press, 1998.

In the case where the etching is executed by ClF₃, as can be seen from Formula (1), the etching is carried out by F₂, which is generated by decomposition of ClF₃. Since the bond energy of Hf—F is 6.73 eV, the bond of Hf—O cannot be broken in view of the above theory; however, in practice, the high dielectric constant oxide film can be thermally etched by ClF₃ because the bond energy of Hf—O is estimated to be lower than 8.30 eV, as shown in the above Table 1, and to be in the middle between 6.73 eV of Hf—F and 5.16 eV of Hf—Cl. According to a report, for example, J. L. Gavartin, University College London, the bond energy of Hf—O—Hf is presumed to be 6.5 eV, and it corresponds to the above estimation.

Those bond energies are different because the layer quality of the HfO₂ film, that is, the interatomic distance of Hf—O, is different, depending on the film formation method of the HfO₂ film. The sample used in the evaluation was fabricated by an Atomic Layer Deposition (ALD) process. It is considered that the bond energy of the film formed by the ALD process is lower than that shown in the above Table 1.

In this evaluation, the HfO₂ film by the ALD process was formed by alternately supplying tetrakis(ethylmethylamino) hafnium (TEMAH) and O₃ at about 230 to 250° C.

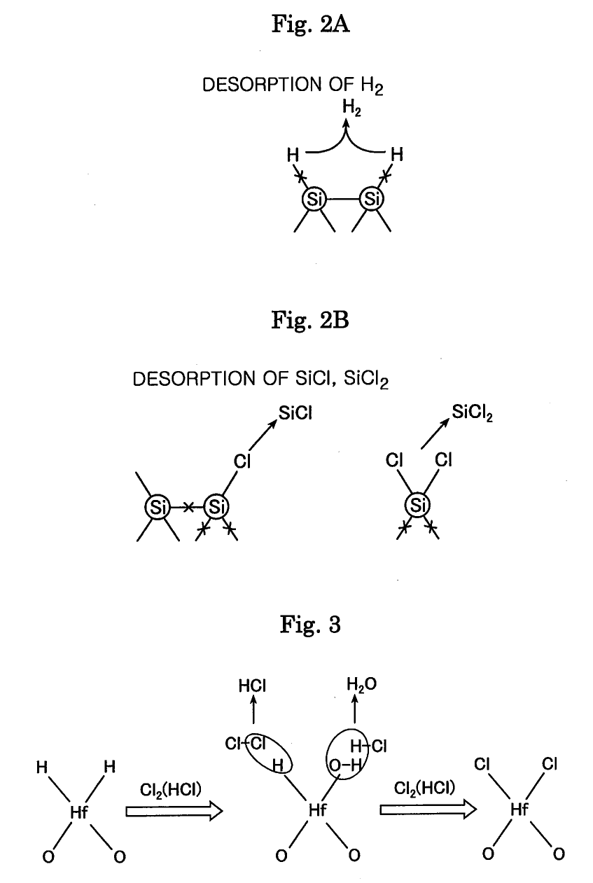

Herein, before describing the reaction in the case where the HfO₂ film is etched by Cl₂, the studies on the chloride formation by Cl₂ etching of Si and its desorption will be reviewed. A document (Surface Science, Vol. 16, No. 6, pp. 373-377, 1996) discloses adsorption and desorption of chlorine atoms on/from a Si surface. The adsorbed chlorine atoms are desorbed in the form of not Cl₂ but SiCl or SiCl₂, so that a Si substrate is etched. As shown in FIG. 2B, the desorption requires the breaking of the Si—Si back-bond of chlorine-adsorbed Si atoms. In this case, the number of the broken Si—Si back-bonds is different according to the adsorption state of chlorine. For example, in the adsorption of SiCl from the Si(100)2×1 surface, as shown in FIG. 2B, three Si—Si bonds should be broken in order to extract SiCl in the monochloride state. Since the extraction of one Si atom from a bulk Si having a diamond structure requires the energy of 88 kcal/mol, the energy of 22 kcal/mol per one Si—Si back-bond is required. Although “kcal/mol” is used as a unit of the bond energy, “eV” shown in the above Table 1 is obtained by the following relational expression: 1 eV=23.069 kcal/mol. In FIG. 2B, the desorption of SiCl requires the energy of 66 kcal/mol, and the desorption of SiCl₂ requires the energy of 44 kcal/mol. FIG. 2A illustrates the desorption of H₂ which requires the energy of 18.2 kcal/mol. Furthermore, the bond energy of SiCl is 85.7 kcal/mol, and the adsorbed Cl atoms are left on the Si surface.

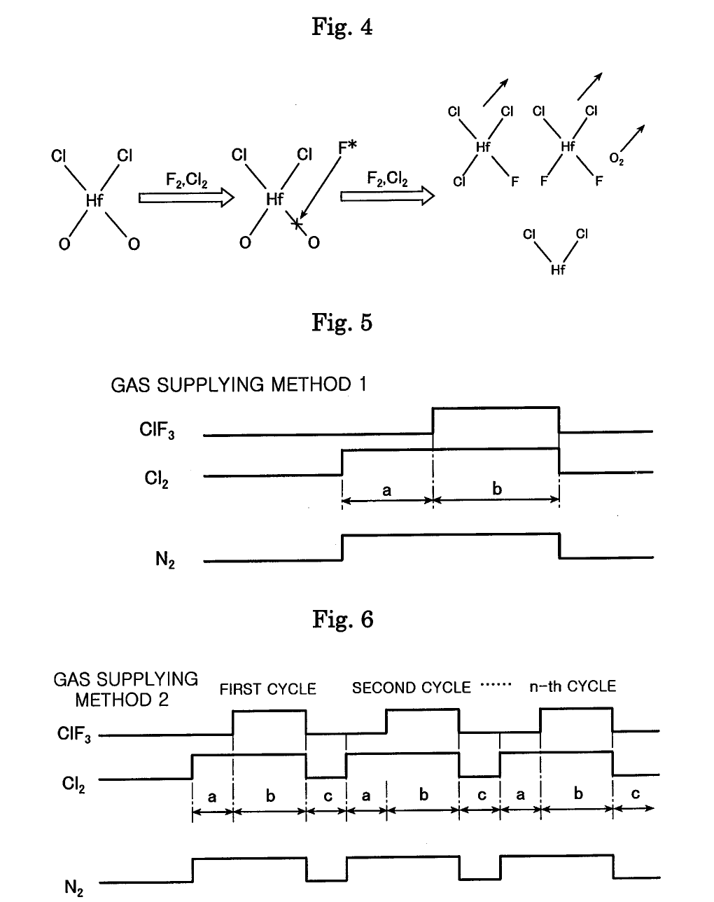

The HfO₂ film can be considered to be similar to the adsorption of Cl on the Si surface. That is, in the HfO₂ bulk, four Hf—O bonds connected to the Hf atom should be broken, but two bonds on the top surface are terminated by Hf—H or Hf—OH. In an ALD film formation model of HfO₂, HfCl₄, which is a Hf raw material, is adsorbed on Hf—OH of the HfO₂ surface, and HCl is desorbed to form Hf—O—HfCl₃ or (Hf—O)₂—HfCl₂, but the etching is considered as an inverse reaction of the above. [R. L. Puurunen, Journal of Applied Physics, Vol. 95 (2004) pp. 4777-4785]. In fact, this can be considered as a mechanism to produce by-product such as HfCl₄ by an etching reaction. As shown in FIG. 3, as a result of supplying the halogen-containing gas, a Cl-terminated film surface is formed. Furthermore, as shown in FIG. 4, by supplying a fluorine-containing gas in addition to the halogen-containing gas, fluorine radical F* is generated, and the fluorine radical breaks the Hf—O bond.

Generally, the bond energy of the Hf—O bond is higher than that of the Hf—Cl bond (see Table 1), and it is expected that the fluorine radical breaks the Hf—Cl bond more easily than the Hf—O bond. However, in the etching model of the HfO₂ film, the relation of the generally bond energy is not always established, and it is considered that the by-product is formed by the breaking of the Hf—O bond, as shown in FIG. 4. That is, since the Hf—O bond in the actual HfO₂ film maintains a significantly lower bond energy than the general Hf—O bond, the bond energy of the Hf—O bond in the actual HfO₂ film can be broken by the fluorine radical. From the above, it is considered that, as shown in FIG. 4, the Hf—O bond is broken by supplying a fluorine-containing gas to the HfO₂ film surface terminated by Cl by the halogen-containing gas, and Cl or F is added to the broken site to form by-products (HfCl₄, HfCl₃F, HfCl₂F₂, and HfClF₃).

In the etching by ClF₃, progress of the etching by F₂ dissociated from ClF₃ is represented in the formula (2), but it is important to perform the etching, without depositing HfF₄ having low vapor pressure on the substrate. As can be seen from the vapor pressure curve of halide and fluoride of Hf, shown in FIG. 1A, the present inventors paid attention to HfCl₄ having higher vapor pressure than HfF₄, and examined the method of desorbing intermediate compound of HfF₄ and HfCl₄ from the substrate. The vapor pressure of the intermediate compound such as HfCl₃F, HfCl₂F₂ or HfClF₃ is not so high as that of HfCl₄, but higher than that of HfF₄, and it was predicted that, in the etching, the intermediate compound is desorbed from the substrate and does not become an etching interference molecule.

As a method of forming the intermediate compound, there is a Cl-substituted structure where the HfO₂ surface is substituted with Cl₂ (or HCl). The HfO₂ surface is generally terminated by —H or —OH, and thus if Cl₂ or HCl is supplied, the HfO₂ surface is terminated by Cl. This step is shown in FIG. 3. As shown in FIG. 3, if HCl is supplied to —OH termination group, H₂O is desorbed to form an Hf—Cl bond. Furthermore, if Cl₂ is supplied to —H termination group, HCl is desorbed to form an Hf—Cl bond. In this manner, the HfO₂ film surface is terminated by Cl.

In the next step, a thermal decomposition process or a plasma process is performed on F₂ to generate an F radical F*. The F radical attacks and breaks the Hf—O bond and simultaneously forms the Hf—F bond. The Hf—O bond is transformed into the Hf—F bond, and simultaneously HfClₓF_{y} (where x and y (y≦3) are integers and x+y=4) is formed and desorbed from the HfO₂ substrate. In this process, Cl₂ is supplied simultaneously when ClF₃ is supplied. Therefore, due to F₂ dissociated from ClF₃, the Hf—O—Hf bond is broken to form the intermediate compounds, such as HfClF₃, HfCl₂F₂, HfCl₃F, and HfCl₄, which have a relatively high vapor pressure. That is, the reaction of the HfO₂ film with the halogen-containing gas (Cl₂ or HCl) and the fluorine-containing gas (ClF₃) forms compounds (HfClF₃, HfCl₂F₂, HfCl₃F, and HfCl₄) containing at least one kind of element (Hf) of the HfO₂ film, the halogen element (Cl), and the fluorine element (F).

Meanwhile, by flowing Cl₂ at the same time, it is possible to increase the probability that the Hf surface side (H-termination group or OH termination group) after dissociation of HfClₓF_{y} is terminated by not F but Cl, thus suppressing the formation of products, such as HfF₄, which have a low vapor pressure. That is, if the partial pressure of Cl₂ is raised, an intermediate product having a high vapor pressure is formed, whereas an etching speed is deteriorated, and if the partial pressure of F₂ is raised, an etching speed is momentarily increased, whereas an intermediate product having a low vapor pressure is formed, so that the etching is stopped. For this reason, it is necessary to choose a ratio of ClF₃ to Cl₂ at which an etching rate is highest. This step is shown in FIG. 4.

As mentioned above, in the etching of the high dielectric constant oxide film such as HfO₂, the HfO₂ surface is first terminated by Cl, and then if Hf—O of the back-bond side is broken by the fluorine-based etching gas, it is considered that HfF₄ susceptible to remain is not formed, and HfClₓF_{y} susceptible to evaporation is formed, and thereafter the etching proceeds.

Next, explanation will be given on a process of supplying an etching gas into a processing chamber as a substrate processing chamber which is supplied with an etching gas.

Methods for supplying ClF₃, which is the fluorine-based etching gas, and Cl₂ or HCl, which is the halogen-based etching gas, are shown in FIG. 5 and FIG. 6. A gas supplying method 1 shown in FIG. 5 is a method that continuously supplies the etching gas to a surface of an etching target substrate, and a gas supplying method 2 shown in FIG. 6 is a method that cyclically supplies the etching gas.

As mentioned above, in order for Cl termination of HfO₂, it is preferable that, by supplying the halogen-based etching gas before supplying the fluorine-based etching gas, the HfO₂ surface is terminated by Cl. In FIG. 5, the halogen-based etching gas is first flown during only a time period “a” and subsequently the fluorine-based etching gas and the halogen-based etching gas are flown during only a time period “b”, and when the etching is completed, the supply of the etching gas is stopped and the processing chamber is evacuated. In the process of supplying the fluorine-based etching gas, a heating process or a plasma process is applied on the gas to generate fluorine radical. In the etching process, inert gas such as N₂ may be supplied at the same time. In the halogen-based gas supplying process of FIG. 5 or FIG. 6, Cl₂ or HCl or a mixed gas of Cl₂ and HCl may flow in the process “a”. This is because, as shown in FIG. 3, the Cl termination mechanisms by Cl₂ and HCl are different according to whether the Hf surface is terminated by H or OH. Furthermore, in the process “b”, it is preferable to flow Cl₂ instead of HCl, so that the Hf surface reconstructed to break away HfClₓF_{y} as a compound having a high vapor pressure can be terminated by Cl.

The gas supplying method 2 is a method that cyclically supplies the etching gas. That is, the gas supplying method 2 is a method that sets a process “a” of supplying a halogen-containing gas and a process “b” of supplying a fluorine-containing gas as one cycle, and repeats this cycle a plurality of times. In the gas supplying method 2, the etching can be performed, with an exhaust valve being closed, during the period “a” and the period “b”. If an etching amount per one cycle is checked, the etching could be performed according to number of the cycles. Moreover, compared with the gas supplying method 1, the gas supplying method 2 has an advantage that the consumption of the etching gas is small.

In the above “Etching principle”, the Hf₂O film as the high dielectric constant oxide film to be etched, ClF₃ as the fluorine-based etching gas, and Cl₂ or HCl as the halogen-based etching gas are exemplified. This “Etching principle” can also be applied to the case where HfO_{y}, ZrO_{y}, AlₓO_{y}, HfSiₓO_{y}, HfAlₓO_{y}, ZrSiO_{y}, and ZrAlO_{y} (where x and y are integers or decimals greater than 0) are used as the high dielectric constant oxide.

Likewise, the fluorine-based etching gas may be fluorine-containing gases, such as nitrogen trifluoride (NF₃), fluorine (F₂), chlorine trifluoride (ClF₃), tetrafluoromethane (CF₄), hexafluoroethane (C₂F₆), octafluoropropane (C₃F₈), hexafluorobutadiene (C₄F₆), sulfur hexafluoride (SF₆), and carbon oxyfluoride (COF₂). The halogen-based etching gas may be chlorine-containing gases, such as chlorine (Cl₂), hydrogen chloride (HCl), and silicon tetrachloride (SiCl₄), or may be bromine-containing gases, such as hydrogen bromide (HBr), boron tribromide (BBr₃), silicon tetrabromide (SiBr₄), and bromine (Br₂).

### Embodiment

Explanation will be given on the embodiments that are very suitable for using the above “Etching principle”, and more particularly, a substrate processing apparatus using the above “Etching principle”, and a cleaning method thereof.

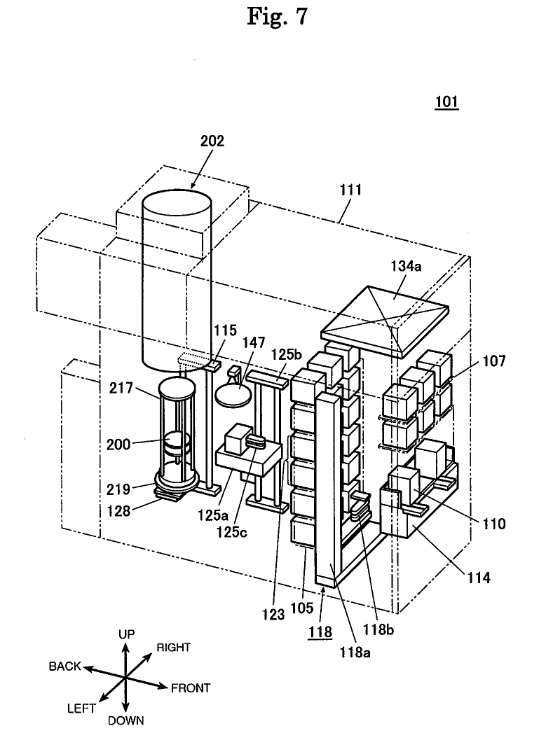

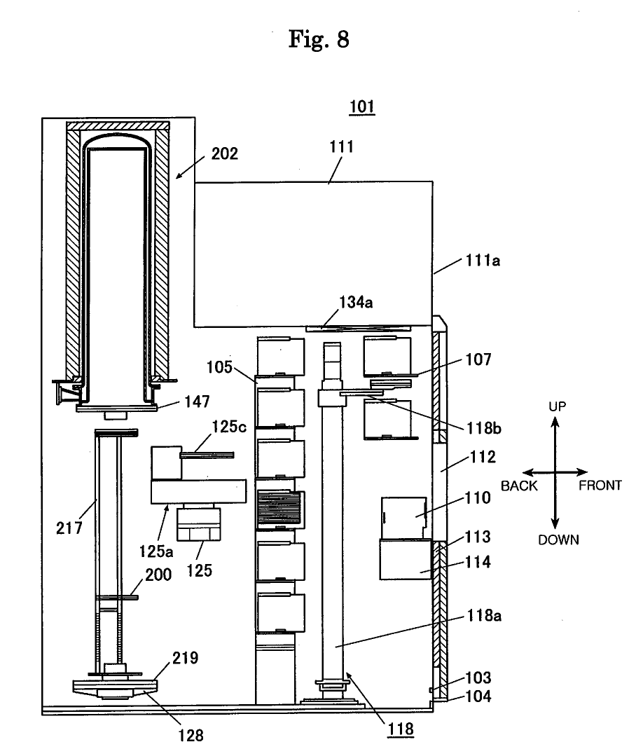

First, a substrate processing apparatus used in the embodiments of the present invention will be described with reference to FIG. 7 and FIG. 8. FIG. 7 is a perspective view of a substrate processing apparatus used in the embodiments of the present invention. FIG. 8 is a side cross-sectional view of the substrate processing apparatus shown in FIG. 7.

As shown in FIG. 7 and FIG. 8, in the substrate processing apparatus 101, a cassette 110 is used, as a wafer carrier, which stores a wafer 200, made of a material such as silicon. The substrate processing apparatus 101 is provided with a housing 111. At the lower part of a front wall 111a of the housing 111, a front maintenance gate 103 is as an opening part opened so that maintenance is possible, and a front maintenance door 104 is installed, which opens and closes the front maintenance gate 103.

At the front maintenance door 104, a cassette carrying-in and carrying-out opening (substrate container carrying-in and carrying-out opening) 112 is installed to communicate inside and outside of the housing 111, and the cassette carrying-in and carrying-out opening 112 is designed to be opened and closed by a front shutter (substrate container carrying-in and carrying-out opening/closing mechanism) 113.

At the inside of the housing 111 of the cassette carrying-in and carrying-out opening 112, a cassette stage (substrate container transfer table) 114 is installed. The cassette 110 is designed to be carried-in on the cassette stage 114, or carried-out from the cassette stage 114, by an in-plant carrying apparatus (not shown).

The cassette stage 114 is put so that the wafer 200 retains a vertical position inside the cassette 110, and a wafer carrying-in and carrying-out opening 112 of the cassette 110 faces an upward direction, by the in-plant carrying apparatus. The cassette stage 114 is configured so that the cassette 110 is rotated 90 degrees counterclockwise in a longitudinal direction to backward of the housing 111, and the wafer 200 inside the cassette 110 takes a horizontal position, and the wafer carrying-in and carrying-out opening of the cassette 110 faces the backward of the housing 111.

At nearly the center portion inside the housing 111 in a front and back direction, a cassette shelf (substrate container placement shelf) 105 is installed to store a plurality of cassettes 110 in a plurality of stages and a plurality of rows. At the cassette shelf 105, a transfer shelf 123 is installed to store the cassettes 110 which are carrying targets of a wafer transfer mechanism 125. In addition, at the upward of the cassette stage 114, a standby cassette shelf 107 is installed to store a standby cassette 110.

Between the cassette stage 114 and the cassette shelf 105, a cassette carrying unit (cassette carrying apparatus) 118 is installed. The cassette carrying unit 118 is configured by a cassette elevator (substrate container elevating mechanism) 118a, which is capable of holding and moving the cassette 110 upward and downward, and a cassette carrying mechanism (cassette container carrying mechanism) 118b as a carrying mechanism. The cassette carrying unit 118 is designed to carry the cassette 110 in and out of the cassette stage 114, the cassette shelf 105, and/or the standby cassette shelf 107 by continuous motions of the cassette elevator 118a and the cassette transfer mechanism 118b.

At the backward of the cassette shelf 105, a wafer transfer mechanism (substrate transfer mechanism) 125 is installed. The wafer transfer mechanism 125 is configured by a wafer transfer unit (wafer transfer unit) 125a, which is capable of horizontally rotating or straightly moving the wafer 200, and a wafer transfer unit elevator (substrate transfer unit elevating mechanism) 125b for moving the wafer transfer unit 125a upward and downward. The wafer transfer unit elevator 125b is installed at the right end portion of the housing 111 of withstand pressure. By the continuous operation of the wafer transfer unit elevator 125b and the wafer transfer unit 125a, the wafer 200 is charged and discharged into/from a boat (substrate holding tool) 217, with tweezers (substrate holding body) 125c of the wafer transfer unit 125a as a placement part of the wafer 200.

As shown in FIG. 8, at the upward of the rear portion of the housing 111, a processing furnace 202 is installed. The lower end portion of the furnace 202 is configured to be opened and closed by a throat shutter (throat opening/closing mechanism) 147.

At the downward of the processing furnace 202, a boat elevator (substrate holding tool elevating mechanism) 115 is installed at the downward of the processing furnace 202, as an elevating mechanism to elevate the boat 217 in the processing furnace 202, and a seal cap 219 as a cap body is horizontally installed in an arm 128 as a connecting tool connected to an elevating table of the boat elevator 115, so that the seal cap 219 vertically supports the boat 217 to close the lower end portion of the processing furnace 202.

The boat 217 is installed with a plurality of holding members, and is configured to hold a plurality of sheets (for example, from about 50 to 150 sheets) of wafers 200 each horizontally, in a state that the centers thereof are aligned and put in a vertical direction.

As shown in FIG. 8, at the upward of the cassette shelf 105, a clean unit 134a is installed for supplying clean air, that is, purified atmosphere. The clean unit 134a is configured by a supply fan and a dust-proof filter, so as to flow clean air through the inside of the housing 111.

Also, as schematically shown in FIG. 8, a clean unit (not shown) configured by a supply fan and a dust-proof filter for supplying clean air is installed in the left end portion of the housing 111, which is the opposite side to the wafer transfer unit elevator 125b and the boat elevator 115, so that the clean air blown from the clean unit (not shown) flows through the wafer transfer unit 125a and the boat 217, and then is exhausted to the outside of the housing 111.

Then, explanation will be given on the operation of the substrate processing apparatus 101.

As shown in FIG. 7 and FIG. 8, before supply of the cassette 110 onto the cassette stage 114, the cassette carrying-in and carrying-out opening 112 is opened by the front shutter 113. Thereafter, the cassette 110 is carried in onto the cassette stage 114 from the cassette carrying-in and carrying-out opening 112. In this time, the cassette 110 is mounted so that the wafer 200 inside the cassette 110 is held in a vertical position, and the wafer carrying-in and carrying-out opening of the cassette 110 faces an upward direction. After that, the cassette 110 is rotated by the cassette stage 114 at 90 degrees clockwise to in a longitudinal direction, so that the wafer 200 inside the cassette 110 takes a horizontal position, and the wafer carrying-in and carrying-out opening of the cassette 110 faces the backward of the housing 111.

Then, the cassette 110 is automatically carried and delivered at a specified shelf position of the cassette shelf 105 or the standby cassette shelf 107 by the cassette carrying unit 118, and stored temporarily and transferred to the transfer shelf 123 from the cassette shelf 105 or the standby cassette shelf 107 by the cassette carrying unit 118, or directly transferred to the transfer shelf 123.

When the cassette 110 is transferred to the transfer shelf 123, the wafer 200 is picked up from the cassette 110 through the wafer carrying-in and carrying-out opening by the tweezers 125c of the wafer transfer unit 125a, and is charged into the boat 217. After transferring the wafer 200 to the boat 217, the wafer transfer unit 125a returns to the cassette 110 and charges the next wafer 200 onto the boat 217.

When predetermined sheets of the wafers 200 are charged onto the boat 217, the lower end portion of the processing furnace 202, which was kept closed by the throat shutter 147, is opened by the throat shutter 147. Subsequently, the boat 217 holding a group of wafers 200 is loaded into the processing furnace 202 by elevating the seal cap 219 by the boat elevator 115. After the loading, an optional processing is applied to the wafer 200 in the processing furnace 202. After the processing, the wafer 200 and the cassette 110 are carried out of the housing 111 in a reverse order of the above.

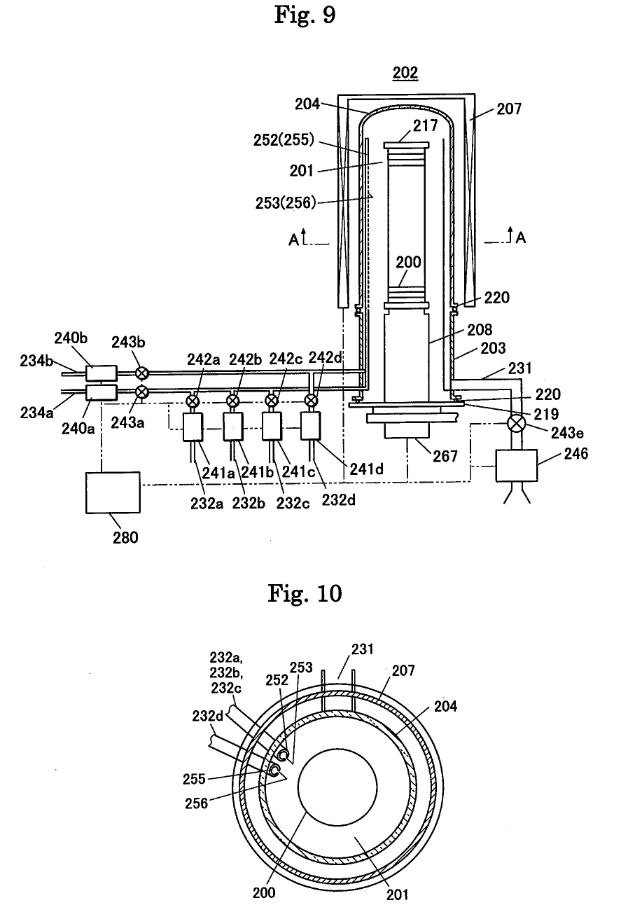

Next, explanation will be given on an etching of high dielectric constant oxide film, as an example, in the processing furnace 202 used in the aforementioned substrate processing apparatus 101 with reference to FIG. 9 and FIG. 10.

FIG. 9 illustrates a schematic configuration of a vertical type substrate processing furnace relevant to the current embodiment, where a processing furnace 202 is shown by a vertical sectional face. FIG. 10 illustrates a cross-sectional view taken along the A-A line of FIG. 9.

In this embodiment, at a flange of the processing furnace 202, introduction ports for a high dielectric constant material, an ozone (O₃), a fluorine-based etching gas, and a halogen-based etching gas are installed. The high dielectric constant material and the O₃ are used in the film formation process, and the fluorine-based etching gas and the halogen-based etching gas are used in the etching process.

At the inside of a heater 207, which is a heating unit (heating means), a reaction tube 204 is installed as a reaction vessel for processing a wafer 200, which is a substrate. At the lower end portion of the reaction tube 204, a manifold 203 made of, for example, stainless steel or the like, is installed via an O-ring, which is a sealing member. The lower opening of the manifold 203 is air-tightly blocked by a seal cap 219, which is a cap body, via the O-ring 220. In the processing furnace 202, a processing chamber 201 is formed by at least the reaction tube 204, the manifold 203 and the seal cap 219.

At the seal cap 219, the boat 217, which is a substrate holding member, is erected via a boat support stand 208, and the boat support stand 208 is designed to be a holding body for holding the boat. Then, the boat 217 is inserted into the processing chamber 201. At the boat 217, a plurality of wafers 200 to be subjected to batch processing are piled in a horizontal position, in a tube axial direction, and in multiple stages. The heater 207 heats the wafer 200 inserted into the processing chamber 201 up to a prescribed temperature.

At the processing chamber 201, four gas supply pipelines (gas supply tubes 232a, 232b, 232c and 232d) are connected as supply routes for supplying a plurality of kinds of gases.

The gas supply pipeline 232a, the gas supply pipeline 232b and the gas supply pipeline 232c are joined with a carrier gas supply pipeline 234a for supplying a carrier gas via mass flow controllers 241a, 241b and 241c, which are flow rate controller, and valves 242a, 242b and 242c, which are open-close valves, in this order from an upper stream direction. At the carrier gas supply pipeline 234a, a mass flow controller 240a, which is a flow rate controller, and a valve 243a, which is an open-close valve, are installed in this order from the upstream direction.

The gas supply pipelines 232a, 232b and 232c are connected to a nozzle 252. The nozzle 252 is provided along an upper inner wall from the lower portion of the reaction tube 204 (along the piling direction of the wafers 200) in an arc-like space between the inner wall of the reaction tube 204, which constitutes the processing chamber 201, and the wafer 200. At the side surface of the nozzle 252, a plurality of gas supply holes 253 are formed, which are supply holes for supplying gases. The gas supply holes 253 each have the same opening area and are formed in the same opening pitch over from the lower portion to the upper portion.

The gas supply pipeline 232d is joined with a carrier gas supply pipeline 234b for supplying a carrier gas via a mass flow controller 241d, which is a flow rate controller, and a valve 242d, which is an open-close valve, in this order from the upstream direction. At the carrier gas supply pipeline 234b, a mass flow controller 240b, which is a flow rate controller, and a valve 243b, which is an open-close valve, are installed in this order from the upstream direction.

The gas supply pipeline 232d is connected to a nozzle 255. The nozzle 255 is provided along an upper inner wall from the lower portion of the reaction tube 204 (along the piling direction of the wafers 200) in an arc-like space between the inner wall of the reaction tube 204, which constitutes the processing chamber 201, and the wafer 200. At the side surface of the nozzle 255, a plurality of gas supply holes are formed, which are supply holes for supplying gases. The gas supply holes 256 each have the same opening area and are formed in the same opening pitch over from the lower portion to the upper portion.

In the present embodiment, gases flowing through the gas supply pipelines 232a, 232b, 232c and 232d are as follows. TetraEthylMethylAminoHafnium (TEMAH), which is an example of a high dielectric constant material, flows through the gas supply pipeline 232a. Cl₂ or HCl, which is an example of a halogen-based etching gas, flows through the gas supply pipeline 232b. ClF₃, which is an example of a fluorine-based etching gas, flows through the gas supply pipeline 232c. O₃, which is an oxidizing agent, flows through the gas supply pipeline 232d.

The gas supply pipelines 232a, 232b, 232c and 232d are supplied with carrier gases, such as N₂, from the carrier gas supply pipelines 234a and 234b and are purged.

The processing chamber 201 is connected to a vacuum pump 246, which is an exhaust unit (exhaust means), via a valve 243e by a gas exhaust pipeline 231, which is an exhaust pipeline for exhausting gas, so as to be vacuum-exhausted. The valve 243e is an open-close valve which opens and closes the valve to evacuate the processing chamber 201 or stop the evacuation of the processing chamber 201, and also adjusts a valve opening degree so that pressure can be adjusted.

At the center portion of the reaction tube 204, the boat 217 is installed, which stores a plurality of wafers 200 in multiple stages at the same intervals, and the boat 217 can be loaded and unloaded into/from the reaction tube 204 by the boat elevator 115 (see FIG. 7). In addition, there is provided a boat rotating mechanism 267 for rotating the boat 217 so as to improve processing uniformity, and by driving the boat rotating mechanism 267, the boat 217 supported by the boat support stand 208 is rotated.

A controller 280, which is a control unit, is connected to the mass flow controllers 240a, 240b, 241a, 241b, 241c and 241d, the valves 242a, 242b, 242c, 242d, 243a, 243b and 243e, the heater 207, the vacuum pump 246, the boat rotating mechanism 267, and the boat elevator 115. The controller 280 controls the flow rate adjustment of the mass flow controllers, the opening and closing operation of the valves, the start and stop of the vacuum pump 246, the rotation speed adjustment of the boat rotating mechanism 267, and the upward and downward movement of the boat elevator 115.

Next, explanation will be given on a cleaning (etching) method of the substrate processing apparatus 101, or an example of a film-formation processing in the substrate processing apparatus 101.

First, an etching processing will be described. In the etching, the wafer 200, without being charged into the boat 217, is loaded into the processing chamber 201. After loading the boat 217 into the processing chamber 201, the following steps, which will be described hereinafter, are executed sequentially.

(Step 1)

In the step 1, Cl₂ or HCl, which is an example of a halogen-based etching gas, is supplied into the processing chamber 201. Cl₂ or HCl is used at a concentration diluted with N₂ from 100% to 20%. The valve 242b is opened, Cl₂ or HCl is flown from the gas supply pipeline 232b to the nozzle 252 and is supplied from the gas supply hole 253 to the processing chamber 201. In the case where Cl₂ or HCl being diluted is used, the valve 243a is also opened, and the carrier gas is flown as gas species (Cl₂ or HCl) from the gas supply pipeline 232b. When Cl₂ or HCl is supplied into the processing chamber 201, the processing chamber 201 is previously vacuum-exhausted, and the valve 243e is opened so that Cl₂ or HCl can be introduced.

(Step 2)

In the step 2, ClF₃, which is an example of a fluorine-based etching gas, is supplied into the processing chamber 201. ClF₃ is used at a concentration diluted with N₂ from 100% to 20%. After predetermined time passes from starting the supply of Cl₂ or HCl in the above step 1, the valve 242c is opened in a state that the valve 242b is kept open (while continuously supplying Cl₂ or HCl), and ClF₃ is flown from the gas supply pipeline 232c to the nozzle 252 and is supplied from the gas supply hole 253 to the processing chamber 201. In the case where ClF₃ being diluted is used, the valve 243a is also opened, and the carrier gas is flown as gas species (ClF₃) from the gas supply pipeline 232c. When ClF₃ is supplied into the processing chamber 201, the processing chamber 201 is previously vacuum-exhausted, and the valve 243e is opened so that ClF₃ can be introduced. Then, the etching is executed at constant intervals by repeating the opening and closing of the valve 243e.

In the above step 2, since ClF₃ is supplied into the processing chamber 201 while Cl₂ or HCl is continuously supplied into the processing chamber 201, Cl₂ or HCl and ClF₃ are mixed in the inside of the processing chamber 201, and the step 2 becomes the same processing of supplying the mixed gas into the processing chamber 201.

Especially, in the above step 2, by controlling the heater 207 by means of the controller 280, the inside of the processing chamber 201 is heated up to predetermined temperature (for example, 300 to 700° C., preferably 350 to 450° C.) to heat the mixed gas (especially, ClF₃), and fluorine radical is generated. At the inside or outside of the processing chamber 201, a known plasma generation apparatus is installed and may be configured to plasma-process the mixed gas (especially, ClF₃) and generate the fluorine radical in the processing chamber 201, or supply the fluorine radical into the processing chamber 201. Furthermore, by controlling the valve 243e by means of the controller 280, pressure inside the processing chamber 201 is maintained at predetermined level (from 1 to 13300 Pa). When the etching is completed, the valves 242b, 242c and 243a are closed so that the inside of the processing chamber 201 is vacuum-exhausted, and then the valve 243a is opened so that the processing chamber 201 is purged by N₂.

In the etching processing executed by the step 1 and the step 2, the supply of Cl₂ or HCl and the supply of ClF₃ may be performed continuously, like the gas supply method 1 of FIG. 5. The supply of Cl₂ or HCl and the supply of ClF₃, like the gas supply method 2 of FIG. 6, may be intermittently performed by setting the combination of one-time step 1 process and step 2 process as one cycle and repeating this cycle prescribed number of times.

(Step 3)

When the processing by the etching gas is completed, film-formation process of the high dielectric constant oxide film is executed. Specifically, after the wafer 200 is transferred to the boat 217, the boat 217 is loaded into the processing chamber 201. In an ALD film formation, a film is formed by alternately supplying TEMAH and O₃ as raw gas (substrate processing gas) into the processing chamber 201. The valve 242a is opened, and TEMAH is flown from the gas supply pipeline 232a to the nozzle 252 and introduced from the gas supply hole 253 to the processing chamber 201. A flow rate of TEMAH is controlled by the mass flow controller 241a. Thereafter, the valve 242d is opened, and O₃ is flown from the gas supply pipeline 232d to the nozzle 255 and introduced from the gas supply hole 256 to the processing chamber 201. A flow rate of O₃ is controlled by the mass flow controller 241d. By the above processing, an HfO film is formed on the wafer 200.

(Step 4)

When maintenance period is reached by several batch repetitions of the above step 3, the etching of the step 1 and the etching of the step 2 are executed to clean the inside of the processing chamber 201 of the substrate processing apparatus 101.

In the aforementioned present embodiment, in the film formation of the step 3, when the HfO₂ film remains as a residual film in the inside of the processing chamber 201 (in the inner wall of the reaction tube 204, the boat 217, and the like), Cl₂ or HCl is first supplied in the subsequent etching process, and ClF₃ is then supplied. Therefore, at first, termination group (—OH, —H) of Hf composing the HfO₂ film is substituted with Cl (see FIG. 3), as explained in the above “Etching principle”, and then the Hf—O bond of the HfO₂ film is specifically attacked by the fluorine radical, so that the Hf—O bond can be broken (see FIG. 4).

In this case, Cl of Cl₂ (or HCl) and F of ClF₃ is bonded to the broken site, and compounds (HfCl₄, HfCl₃F, HfCl₂F₂, HfClF₃), which contain Hf composing the HfO₂, Cl of Cl₂ (or HCl), and F of ClF₃, are formed as easily evaporable intermediate products, and the HfO₂ film becomes the above compound and are removed from the processing chamber 201 (see FIG. 4). From the above, the HfO₂ film remaining as the residual film can be adsorbed from the attachment site inside the processing chamber 201, thus making it possible to efficiently remove the HfO₂ film, which is a high dielectric constant oxide film difficult to be etched by the fluorine-containing gas alone.

Furthermore, in the present embodiment, in the above step 2, by continuously supplying Cl₂ or HCl from the above step 1, termination group of HfO₂, which is formed newly on the uppermost surface of the HfO₂ film after the intermediate product is formed and adsorbed, can be substituted with Cl, thus suppressing or preventing the formation of HfF₄, which disturbs the etching even when the intermediate product is once desorbed.

In the preferred embodiment of the present invention, the HfO₂ film is exemplified as the high dielectric constant oxide film to be etched, but it can be considered that even in the case where HfO_{y}, ZrO_{y}, AlₓO_{y}, HfSiₓO_{y}, HfAlₓO_{y}, ZrSiO_{y}, and ZrAlO_{y} (where x and y are integers or decimals greater than 0) are used, they are etched as the above.

Furthermore, ClF₃ as the fluorine-based etching gas and Cl₂ or HCl as the chlorine-based gas are exemplified, but the fluorine-based etching gas may be fluorine-containing gases, such as nitrogen trifluoride (NF₃), fluorine (F₂), chlorine trifluoride (ClF₃), tetrafluoromethane (CF₄), hexafluoroethane (C₂F₆), octafluoropropane (C₃F₈), hexafluorobutadiene (C₄F₆), sulfur hexafluoride (SF₆), and carbon oxyfluoride (COF₂). The halogen-based etching gas may be chlorine-containing gases, such as chlorine (Cl₂), hydrogen chloride (HCl), and silicon tetrachloride (SiCl₄), or may be bromine-containing gases, such as hydrogen bromide (HBr), boron tribromide (BBr₃), silicon tetrabromide (SiBr₄), and bromine (Br₂).

Moreover, in the preferred embodiment of the present invention, the substrate processing apparatus 101 as a film-formation apparatus which forms a film by an Atomic Layer Deposition (ALD) method is exemplified above, but the apparatus configuration or cleaning method relevant to the preferred embodiment of the present invention can be used in an apparatus which forms a film by a CVD method. The ALD method is a technique of supplying process gases, which are at least two kinds of raw materials used in film formation, onto a substrate alternately one by one, making the process gases adsorbed on the substrate by one atomic unit, and performing film formation by using a surface reaction.

Explanation was given on the preferred embodiments of the present invention. According to a preferred embodiment of the present invention, as a cleaning method for removing a film attached to the inside of a processing chamber of a substrate processing apparatus which forms a desired film on a substrate by supplying a source gas, there is provided a first cleaning method including: a step of supplying a halogen-containing gas into the processing chamber; and a step of supplying a fluorine-containing gas into the processing chamber, after starting the supply of the halogen-containing gas, wherein, in the step of supplying the fluorine-containing gas, the fluorine-containing gas is supplied while supplying the halogen-containing gas into the processing chamber.

Preferably, the halogen-containing gas is a chlorine-containing gas or a bromine-containing gas, and does not contain a fluorine-containing gas. In addition, preferably, the chlorine-containing gas is chlorine (Cl₂), hydrogen chloride (HCl), or silicon tetrachloride (SiCl₄), and the bromine-containing gas is hydrogen bromide (HBr), boron tribromide (BBr₃), silicon tetrabromide (SiBr₄), and bromine (Br₂).

According to the first cleaning method, the halogen-containing gas (for example, Cl₂ or HCl) is first supplied into the processing chamber, and the fluorine-containing gas (for example, ClF₃) is then supplied. Therefore, at first, termination group of an element (for example, Hf) composing a film is substituted with an element (for example, Cl) derived from the halogen-containing gas, and thereafter a predetermined bond (for example, Hf—O bond) of the film is specifically attacked by a fluorine derived from the fluorine-containing gas, so that the corresponding bond can be broken. Therefore, the element composing the film can be desorbed from the attachment site inside the processing chamber, thus making it possible to efficiently remove the film, such as a high dielectric constant oxide film, which is difficult to be etched by the fluorine-containing gas alone. Furthermore, in this case, in the step of supplying the fluorine-containing gas, since the halogen-containing gas is also supplied continuously from the previous step, termination group of the film, which is formed newly on the uppermost surface after the predetermined bond is broken, can be substituted with an halogen element, thus suppressing or preventing the formation of fluoride of the element composing the film.

According to another embodiment of the present invention, as a cleaning method for removing a film attached to the inside of a processing chamber of a substrate processing apparatus which forms a high dielectric constant oxide film on a substrate by supplying a source gas, there is provided a second cleaning method including: a step of supplying a halogen-containing gas into the processing chamber; and a step of supplying a fluorine-containing gas into the processing chamber while supplying the halogen-containing gas, after starting the supply of the halogen-containing gas, wherein, in the step of supplying the halogen-containing gas, termination group of the surface of the high dielectric constant oxide film, which is attached to the inside of the processing chamber, is substituted with a halogen element, and in the step of supplying the fluorine-containing gas, a thermal decomposition process or a plasma process is applied to fluorine of the fluorine-containing gas to generate fluorine radical, and a bond of a metal element and an oxygen element contained in the high dielectric constant oxide film is attacked and broken by the fluorine radical, and a halogen element or a fluorine element is added to the broken site, and at least one of a first product composed of the metal element and the halogen element, and a second product composed of the metal element, the halogen element and the fluorine element is formed.

For example, in the case of removing HfO₂ used as the high dielectric constant oxide film, when Cl₂ as the halogen-containing gas and ClF₃ as the fluorine-containing gas are used, in the step of supplying the above halogen-containing gas, the termination group (—OH, —H) of HfO₂ is substituted with Cl. Thereafter, in the step of supplying the fluorine-containing gas, a thermal decomposition process or a plasma process is applied to F of ClF₃ to generate fluorine radical F*, which breaks Hf—O, and Cl or F is added and bonded to the broken site to form an intermediate product, such as HfCl₄, HfCl₃F, HfCl₂, HfClF₃ or the like. That is, according to the second cleaning method, the easily evaporable intermediate product as above is spontaneously formed, thus suppressing or preventing the formation of HfF₄, which disturbs the etching of the HfO₂ film, so that the HfO₂ film can be effectively etched. Furthermore, according to the second cleaning method, in the step of supplying the fluorine-containing gas, since the halogen-containing gas is also supplied continuously from the previous step, termination group of HfO₂, which is formed newly on the uppermost surface after the intermediate product is desorbed by breaking Hf—O bond, can be substituted with Cl, thus suppressing or preventing the formation of HfF₄ even after the intermediate product is once desorbed.

Moreover, according to another preferred embodiment of the present invention, there is provided a substrate processing apparatus including: a processing chamber for processing a substrate; a first supply member for supplying a substrate processing gas into the processing chamber; a second supply pipeline for supplying a halogen-containing gas into the processing chamber; a third supply pipeline for supplying a fluorine-containing gas into the processing chamber; and a controller for controlling the second supply pipeline and the third supply pipeline, first supplying the halogen-containing gas through the second supply pipeline into the processing chamber, and then supplying the fluorine-containing gas through the third supply pipeline into the processing chamber.

According to the substrate processing apparatus, the controller controls the second supply pipeline and the third supply pipeline to first supply the halogen-containing gas into the processing chamber and then supply the fluorine-containing gas into the processing chamber, so that termination group of an element (for example, Hf) composing a film attached to the inside of the processing chamber, as a film derived from the substrate processing gas, is first substituted with an element (for example, Cl) derived from the halogen-containing gas (for example, Cl₂ or HCl), and thereafter a predetermined bond (for example, Hf—O bond) of the film is specifically attacked by fluorine derived from the fluorine-containing gas (for example, ClF₃), so that the corresponding bond can be broken. Therefore, the element composing the film can be desorbed from the attachment site inside the processing chamber, thus making it possible to efficiently remove the film, such as a high dielectric constant oxide film, which is difficult to be etched by the fluorine-containing gas alone.

According to an aspect of the present invention, by first supplying the halogen-containing gas (for example, Cl₂ or HCl) into the processing chamber, and then supplying the fluorine-containing gas (for example, ClF₃), termination group of an element (for example, Hf) composing a film at first is substituted with an element (for example, Cl) derived from the halogen-containing gas, and thereafter a predetermined bond (for example, Hf—O bond) of the film is specifically attacked by fluorine derived from the fluorine-containing gas, so that the corresponding bond can be broken. From the above, the element composing the film can be desorbed from the attachment site inside the processing chamber, thus making it possible to efficiently remove the film, such as a high dielectric constant oxide film, which is difficult to be etched by the fluorine-containing gas alone.

According to another aspect of the present invention, by first supplying the halogen-containing gas (for example, Cl₂ or HCl) into the processing chamber, and then supplying the fluorine-containing gas (for example, ClF₃), the easily evaporable product composed of the metal element (for example, Hf), which is contained in the metal oxide film, the halogen element and the fluorine element is formed, so that the formation of fluoride of the metal element is suppressed or prevented, and the metal element composing of the metal oxide film can be desorbed, as the product, from the attachment site inside the processing chamber.

From the above, it is possible to efficiently remove the metal oxide film such as the high dielectric constant oxide film that is difficult to be etched by the fluorine-containing gas alone.

According to another aspect of the present invention, the mixed gas of the halogen-containing gas (for example, Cl₂ or HCl) and the fluorine-containing gas (for example, ClF₃) is supplied into the processing chamber, and the easily evaporable product composed of the metal element (for example, Hf), which is contained in the high dielectric constant oxide film, the halogen element and the fluorine element is formed, so that the formation of fluoride of the metal element is suppressed or prevented, and the metal element composing of the metal oxide film can be desorbed, as the product, from the attachment site inside the processing chamber.

(Supplementary Note)

The present invention also includes the following embodiments.

(Supplementary Note 1)

According to an embodiment of the present invention, there is provided a cleaning method for removing a film attached to the inside of a processing chamber of a substrate processing apparatus which forms a desired film on a substrate by supplying a source gas, the cleaning method including: a step of supplying a halogen-containing gas into the processing chamber; and a step of supplying a fluorine-containing gas into the processing chamber, after starting the supply of the halogen-containing gas, wherein, in the step of supplying the fluorine-containing gas, the fluorine-containing gas is supplied while supplying the halogen-containing gas into the processing chamber.

(Supplementary Note 2)

In the cleaning method of Supplementary Note 1, it is preferable that the film to be removed as the film attached to the inside of the processing chamber is a high dielectric constant oxide film containing a kind of a metal element.

(Supplementary Note 3)

In the cleaning method of Supplementary Note 1, it is preferable that the film which is attached to the inside of the processing chamber reacts with the halogen-containing gas and the fluorine-containing gas to form a compound containing at least one element among composition of the film which is attached to the inside of the processing chamber, a halogen element, and a fluorine element.

(Supplementary Note 4)

In the cleaning method of Supplementary Note 2, it is preferable that the high dielectric constant oxide film is any one of HfO_{y}, ZrO_{y}, AlₓO_{y}, HfSiₓO_{y}, HfAlₓO_{y}, ZrSiO_{y}, and ZrAlO_{y}.

(Supplementary Note 5)

In the cleaning method of Supplementary Note 1, it is preferable that the step of supplying the halogen-containing gas, and the step of supplying the fluorine-containing gas while supplying the halogen-containing gas are set as one cycle, and this cycle is repeated a plurality of times.

(Supplementary Note 6)

In the cleaning method of Supplementary Note 1, it is preferable that the halogen-containing gas is a chlorine-containing gas or a bromine-containing gas.

(Supplementary Note 7)

In the cleaning method of Supplementary Note 1, it is preferable that the fluorine-containing gas is any one of nitrogen trifluoride (NF₃), fluorine (F₂), chlorine trifluoride (ClF₃), tetrafluoromethane (CF₄), hexafluoroethane (C₂F₆), octafluoropropane (C₃F₈), hexafluorobutadiene (C_{4F}₆), sulfur hexafluoride (SF₆), and carbon oxyfluoride (COF₂), and the halogen-containing gas is any one of chlorine (Cl₂), hydrogen chloride (HCl), silicon tetrachloride (SiCl₄), hydrogen bromide (HBr), boron tribromide (BBr₃), silicon tetrabromide (SiBr₄), and bromine (Br₂).

(Supplementary Note 8)

In the cleaning method of Supplementary Note 1, it is preferable that, by the supply of the halogen-containing gas and the fluorine-containing gas, termination group existing on the surface of the film which is attached to the inside of the processing chamber is substituted with a halogen element, an oxygen element bonded with a metal element contained in the film is substituted with a halogen element or a fluorine element, and a product composed of the metal element, the halogen element and the fluorine element is formed.

(Supplementary Note 9)

In the cleaning method of Supplementary Note 1, it is preferable that, in the step of supplying the halogen-containing gas, termination group of the surface of the film, which is attached to the inside of the processing chamber, is substituted with a halogen element, and in the step of supplying the fluorine-containing gas, a thermal decomposition process or a plasma process is applied to fluorine contained in the fluorine-containing gas to generate fluorine radical, and a bond of a metal element and an oxygen element contained in the film is broken by the fluorine radical, and a halogen element or a fluorine element is added to a broken site of the film, and at least one of a first product which is composed of the metal element and the halogen element, and a second product which is composed of the metal element, the halogen element and the fluorine element is formed.

(Supplementary Note 10)

According to another embodiment of the present invention, there is provided a cleaning method for removing a first high dielectric constant oxide film attached to the inside of a processing chamber of a substrate processing apparatus which forms a second high dielectric constant oxide film on a substrate by supplying a source gas, the cleaning method including: a step of supplying a mixed gas of a halogen-containing gas and a fluorine-containing gas into the processing chamber, wherein, by the supply of the halogen-containing gas and the fluorine-containing gas, termination group existing on the surface of the first high dielectric constant oxide film is substituted with a halogen element, an oxygen element bonded with a metal element contained in the first high dielectric constant oxide film is substituted with a halogen element or a fluorine element, and a product composed of the metal element, the halogen element and the fluorine element is formed.

(Supplementary Note 11)

In the cleaning method of Supplementary Note 10, it is preferable that the first and the second high dielectric constant oxide films are any one of HfO_{y}, ZrO_{y}, AlₓO_{y}, HfSiₓO_{y}, HfLAMO_{y}, ZrSiO_{y}, and ZrAlO_{y}.

(Supplementary Note 12)

In the cleaning method of Supplementary Note 10, it is preferable that the halogen-containing gas is a chlorine-containing gas or a bromine-containing gas.

(Supplementary Note 13)

In the cleaning method of Supplementary Note 10, it is preferable that the fluorine-containing gas is any one of nitrogen trifluoride (NF₃), fluorine (F₂), chlorine trifluoride (ClF₃), tetrafluoromethane (CF₄), hexafluoroethane (C₂F₆), octafluoropropane (C₃F₈), hexafluorobutadiene (C_{4F}₆), sulfur hexafluoride (SF₆), and carbon oxyfluoride (COF₂), and the halogen-containing gas is any one of chlorine (Cl₂), hydrogen chloride (HCl), silicon tetrachloride (SiCl₄), hydrogen bromide (HBr), boron tribromide (BBr₃), silicon tetrabromide (SiBr₄), and bromine (Br₂).

(Supplementary Note 14)

In the cleaning method of Supplementary Note 10, it is preferable that, by the supply of the halogen-containing gas, termination group existing on the surface of the first high dielectric constant oxide film which is attached to the inside of the processing chamber is substituted with a halogen element, and, by the supply of the fluorine-containing gas, a thermal decomposition process or a plasma process is applied to fluorine contained in the fluorine-containing gas to generate fluorine radical, and a bond of a metal element and an oxygen element contained in the first high dielectric constant film is broken by the fluorine radical, and a halogen element or a fluorine element is added to a broken site of the first high dielectric constant film, and at least one of a first product, which is composed of the metal element and the halogen element, and a second product, which is composed of the metal element, the halogen element and the fluorine element, is formed.

(Supplementary Note 15)

According to another embodiment of the present invention, there is provided a substrate processing apparatus, including: a processing chamber for processing a substrate; a first supply pipeline for supplying a substrate processing gas into the processing chamber; a second supply pipeline for supplying a halogen-containing gas into the processing chamber; a third supply pipeline for supplying a fluorine-containing gas into the processing chamber; and a controller for controlling the second supply pipeline and the third supply pipeline, first supplying the halogen-containing gas through the second supply pipeline into the processing chamber, and then supplying the fluorine-containing gas through the third supply pipeline into the processing chamber.

(Supplementary Note 16)

In the substrate processing apparatus of Supplementary Note 15, it is preferable that the halogen-containing gas is a chlorine-containing gas or a bromine-containing gas.

(Supplementary Note 17)

In the substrate processing apparatus of Supplementary Note 15, it is preferable that the fluorine-containing gas is any one of nitrogen trifluoride (NF₃), fluorine (F₂), chlorine trifluoride (ClF₃), tetrafluoromethane (CF₄), hexafluoroethane (C₂F₆), octafluoropropane (C₃F₈), hexafluorobutadiene (C₄F₆), sulfur hexafluoride (SF₆), and carbon oxyfluoride (COF₂), and the halogen-containing gas is any one of chlorine (Cl₂), hydrogen chloride (HCl), silicon tetrachloride (SiCl₄), hydrogen bromide (HBr), boron tribromide (BBr₃), silicon tetrabromide (SiBr₄), and bromine (Br₂).

What is claimed is:

1. A cleaning method for removing a film attached to the inside of a processing chamber of a substrate processing apparatus which forms a desired film on a substrate by supplying a source gas, the cleaning method comprising:
a step of supplying a halogen-containing gas into the processing chamber; and
a step of supplying a fluorine-containing gas into the processing chamber, after starting the supply of the halogen-containing gas,
wherein, in the step of supplying the fluorine-containing gas, the fluorine-containing gas is supplied while supplying the halogen-containing gas into the processing chamber.

2. The cleaning method of claim 1, wherein the film to be removed as the film attached to the inside of the processing chamber is a high dielectric constant oxide film containing a kind of a metal element.

3. The cleaning method of claim 1, wherein the film which is attached to the inside of the processing chamber reacts with the halogen-containing gas and the fluorine-containing gas to form a compound containing at least one element among composition of the film which is attached to the inside of the processing chamber, a halogen element, and a fluorine element.

4. The cleaning method of claim 2, wherein the high dielectric constant oxide film is any one of HfO_{y}, ZrO_{y}, AlₓO_{y}, HfSiₓO_{y}, HfAlₓO_{y}, ZrSiO_{y}, and ZrAlO_{y}.

5. The cleaning method of claim 1, wherein the step of supplying the halogen-containing gas, and the step of supplying the fluorine-containing gas while supplying the halogen-containing gas are set as one cycle, and this cycle is repeated a plurality of times.

6. The cleaning method of claim 1, wherein the halogen-containing gas is a chlorine-containing gas or a bromine-containing gas.

7. The cleaning method of claim 1, wherein the fluorine-containing gas is any one of nitrogen trifluoride (NF₃), fluorine (F₂), chlorine trifluoride (ClF₃), tetrafluoromethane (CF₄), hexafluoroethane (C₂F₆), octafluoropropane (C₃F₈), hexafluorobutadiene (C₄F₆), sulfur hexafluoride (SF₆), and carbon oxyfluoride (COF₂), and the halogen-containing gas is any one of chlorine (Cl₂), hydrogen chloride (HCl), silicon tetrachloride (SiCl₄), hydrogen bromide (HBr), boron tribromide (BBr₃), silicon tetrabromide (SiBr₄), and bromine (Br₂).

8. The cleaning method of claim 1, wherein, by the supply of the halogen-containing gas and the fluorine-containing gas, termination group existing on the surface of the film which is attached to the inside of the processing chamber is substituted with a halogen element, an oxygen element bonded with a metal element contained in the film is substituted with a halogen element or a fluorine element, and a product composed of the metal element, the halogen element and the fluorine element is formed.

9. The cleaning method of claim 1, wherein, in the step of supplying the halogen-containing gas, termination group of the surface of the film, which is attached to the inside of the processing chamber, is substituted with a halogen element, and in the step of supplying the fluorine-containing gas, a thermal decomposition process or a plasma process is applied to fluorine contained in the fluorine-containing gas to generate fluorine radical, and a bond of a metal element and an oxygen element contained in the film is broken by the fluorine radical, and a halogen element or a fluorine element is added to a broken site of the film, and at least one of a first product which is composed of the metal element and the halogen element, and a second product which is composed of the metal element, the halogen element and the fluorine element is formed.

10. A cleaning method for removing a first high dielectric constant oxide film attached to the inside of a processing chamber of a substrate processing apparatus which forms a second high dielectric constant oxide film on a substrate by supplying a source gas, the cleaning method comprising:
a step of supplying a mixed gas of a halogen-containing gas and a fluorine-containing gas into the processing chamber,
wherein, by the supply of the halogen-containing gas and the fluorine-containing gas, termination group existing on the surface of the first high dielectric constant oxide film is substituted with a halogen element, an oxygen element bonded with a metal element contained in the first high dielectric constant oxide film is substituted with a halogen element or a fluorine element, and a product composed of the metal element, the halogen element and the fluorine element is formed.

11. The cleaning method of claim 10, wherein the first and the second high dielectric constant oxide films are any one of HfO_{y}, ZrO_{y}, AlₓO_{y}, HfSiₓO_{y}, HEAlₓO_{y}, ZrSiO_{y}, and ZrAlO_{y}.

12. The cleaning method of claim 10, wherein the halogen-containing gas is a chlorine-containing gas or a bromine-containing gas.

13. The cleaning method of claim 10, wherein the fluorine-containing gas is any one of nitrogen trifluoride (NF₃), fluorine (F₂), chlorine trifluoride (ClF₃), tetrafluoromethane (CF₄), hexafluoroethane (C₂F₆), octafluoropropane (C₃F₈), hexafluorobutadiene (C₄F₆), sulfur hexafluoride (SF₆), and carbon oxyfluoride (COF₂), and the halogen-containing gas is any one of chlorine (Cl₂), hydrogen chloride (HCl), silicon tetrachloride (SiCl₄), hydrogen bromide (HBr), boron tribromide (BBr₃), silicon tetrabromide (SiBr₄), and bromine (Br₂).

14. The cleaning method of claim 10, wherein, by the supply of the halogen-containing gas, termination group existing on the surface of the first high dielectric constant oxide film which is attached to the inside of the processing chamber is substituted with a halogen element, and, by the supply of the fluorine-containing gas, a thermal decomposition process or a plasma process is applied to fluorine contained in the fluorine-containing gas to generate fluorine radical, and a bond of a metal element and an oxygen element contained in the first high dielectric constant film is broken by the fluorine radical, and a halogen element or a fluorine element is added to a broken site of the first high dielectric constant film, and at least one of a first product which is composed of the metal element and the halogen element, and a second product which is composed of the metal element, the halogen element and the fluorine element is formed.

15. A substrate processing apparatus, comprising:
a processing chamber for processing a substrate;
a first supply pipeline for supplying a substrate processing gas into the processing chamber;
a second supply pipeline for supplying a halogen-containing gas into the processing chamber;
a third supply pipeline for supplying a fluorine-containing gas into the processing chamber; and
a controller for controlling the second supply pipeline and the third supply pipeline, first supplying the halogen-containing gas through the second supply pipeline into the processing chamber, and then supplying the fluorine-containing gas through the third supply pipeline into the processing chamber.

16. The substrate processing apparatus of claim 15, wherein the halogen-containing gas is a chlorine-containing gas or a bromine-containing gas.

17. The substrate processing apparatus of claim 15, wherein the fluorine-containing gas is any one of nitrogen trifluoride (NF₃), fluorine (F₂), chlorine trifluoride (ClF₃), tetrafluoromethane (CF₄), hexafluoroethane (C₂F₆), octafluoropropane (C₃F₈), hexafluorobutadiene (C₄F₆), sulfur hexafluoride (SF₆), and carbon oxyfluoride (COF₂), and the halogen-containing gas is any one of chlorine (Cl₂), hydrogen chloride (HCl), silicon tetrachloride (SiCl₄), hydrogen bromide (HBr), boron tribromide (BBr₃), silicon tetrabromide (SiBr₄), and bromine (Br₂).
